(19) United States
(12) Patent Application Publication
(10) Pub. No.: US 2008/0230882 A1
(43) Pub. Date: Sep. 25, 2008

(54) CHIP PACKAGE STRUCTURE

(76) Inventors: Mei-Lin Hsieh, Kaohsiung (TW); Chih-Hung Hsu, Kaohsiung (TW); Kuang-Hsiung Chen, Kaohsiung (TW)

Correspondence Address: Muncy, Geissler, Olds & Lowe, PLLC, P.O. BOX 1364, FAIRFAX, VA, 22038-1364, US

(21) Appl. No.: 12/051,403

(22) Filed: Mar. 19, 2008

(30) Foreign Application Priority Data
Mar. 23, 2007 (TW) 96110243

(51) Int. Cl. H01L 23/495

(52) U.S. Cl. 257/676; 257/E23.031

(57) ABSTRACT

A chip package structure includes a die pad of which at least a notch is formed on at least one side and opposite to a mold gate. The die pad contributes to accelerating the injection of an encapsulating material, so as to exhaust the air in the mold in time, before the encapsulating material solidifies during the molding step, thereby overcoming or at least improving the problem of defects such as air bubbles in the encapsulation.

### RELATED APPLICATIONS

This application claims priority to Taiwan Application Serial Number 96110243, filed Mar. 23, 2007, which is herein incorporated by reference.

### FIELD OF THE INVENTION

This invention relates generally to a chip package structure, and more particularly, to a chip package structure of a quad flat package (QFP).

### BACKGROUND OF THE INVENTION

Integrated circuits (IC) are packaged in various kinds chip package, wherein one of the very common packages is the quad flat package (QFP). In the QFP structure, a leadframe is provided first, wherein the leadframe has a die pad and a plurality of internal leads disposed on a peripheral of the die pad, and a plurality of external leads are connected with the internal leads. And then, a chip is bounded on the die pad by solder balls, for example, and the chip is electrically connected with internal leads by a plurality of leads. Next, an encapsulation material covers the chip, the die pad, the internal leads, the wires, and it fills the space between the chip and the die pad, so as to expose the external leads and complete the chip package process. The packaged chip is electrically connected with outside devices through solder balls and the external leads.

Reference is made to FIG. 1, which depicts a cross-sectional diagram of a prior chip package structure. The chip package structure 100 is a QFP structure, which comprises a leadframe 101 having a plurality of internal leads 103 and a die pad 105, a chip 120 disposed on the die pad 105, a plurality of wires 130 for electrically connecting the chip 120 and the internal leads 103, and an encapsulation 140 covering the leadframe 101, the chip 120 and the wires 130. The internal leads 103 forms a first planar surface shown as a dotted line 161, for defining a projection region 161a. The die pad 105 is disposed in the projection region 161a and has a second planar surface shown as a dotted line 163 and lower than the first planar surface formed by the internal leads 103, being so-called a “downset” die pad. External leads 107 typically are connected with the internal leads 103 and exposed from the encapsulation 140.

Reference is made to FIG. 2, which depicts a partial top view of a chip and a leadframe in prior art. The leadframe 101 further comprises a plurality of internal leads 103, for example, four internal leads 103 disposed in the peripheral of the die pad 105. Typically, an area of the chip 120 is smaller than the peripheral area 109 of the die pad 105.

Reference is made to FIG. 3, which depicts a cross-sectional diagram of a chip package structure during the molding process in prior art. During the molding step, the chip 120, the die pad 105, the internal leads 103 of the leadframe 101 and the wires 130 are disposed in a chamber 151 of a mold 150. An encapsulation material (not shown) is injected into the chamber 151 from a mold gate 153 of the mold 150 by applying a high pressure, and the injected encapsulation material fills the chamber 151 in the direction of the dotted lines 155 and 157, respectively, and covers the chip 120, the die pad 105, the internal leads 103 of the leadframe 101 and the wires 130. The air is exhausted from the mold before the encapsulation material solidifies.

Reference is made to FIG. 4, which depicts a cross-sectional diagram of a chip package structure after completion of the molding process in prior art. The downset die pad has an upper space 141 above the chip 120 larger than a lower space 143 below the die pad 105 because the area of the chip 120 is smaller than the peripheral area 109 of the die pad 105. However, when the encapsulation material is being injected into the chamber 151 through the mold gate 153 during the molding step, the filling speed of the encapsulation material in the direction of the dotted line 151 above the chip 120 is faster so that it can flow back into the lower space 143 below the die pad 105 opposite to the mold gate 153, and impedes air from being exhausted from the lower space 143 below the die pad 105. After the encapsulation material solidifies, the resultant encapsulation 140 has some defects such as air bubbles 145 and the like, thereby affecting the packaging quality of the chip package structure severely.

### SUMMARY OF THE INVENTION

Accordingly, an aspect of the present invention provides a chip package structure, which includes a die pad of which at least a notch is formed on at least one side and opposite to a mold gate, thereby overcoming or at least improving the problem of defects such as air bubbles in the encapsulation.

According to the aforementioned aspect of the present invention, the chip package structure of a preferred embodiment comprises a leadframe having a plurality of internal leads and a die pad, a chip disposed on the die pad, a plurality of wires electrically connecting the chip with the internal leads, and an encapsulation covering the chip, the die pad, the internal leads and the wires. In general, the internal leads form a first planar surface to define a projection region. The die pad is disposed in the projection region and has a second planar surface lower than the first planar surface, wherein at least one side of the die pad has a notch disposed thereon, the notch is disposed in a peripheral area of the die pad and opposite to a mold gate. An area of the chip is smaller than the peripheral area of the die pad, and the chip covers a portion of the notch.

In an embodiment, at least two sides of the die pad also have a notch, respectively, and one of the notches opposite to the mold gate. The notch is a rectangular or curved notch. A contact area between the die pad and the chip ranges from 10 percent to 80 percent of the area of the chip.

With application to the aforementioned chip package structure of the present invention, a notch is formed on at least one side of the die pad to accelerate the injection of an encapsulating material, so as to exhaust the air in the mold before the encapsulating material solidifies during the molding step, thereby overcoming or at least improving the problem of defects such as air bubbles in the encapsulation.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a cross-sectional diagram of a prior chip package structure;

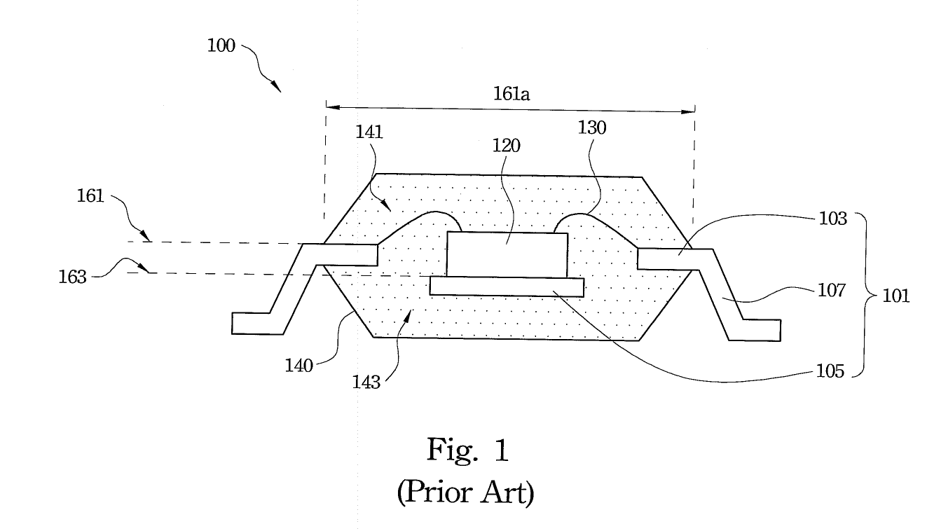

FIG. 2 is a partial top view of a chip and a leadframe in prior art;

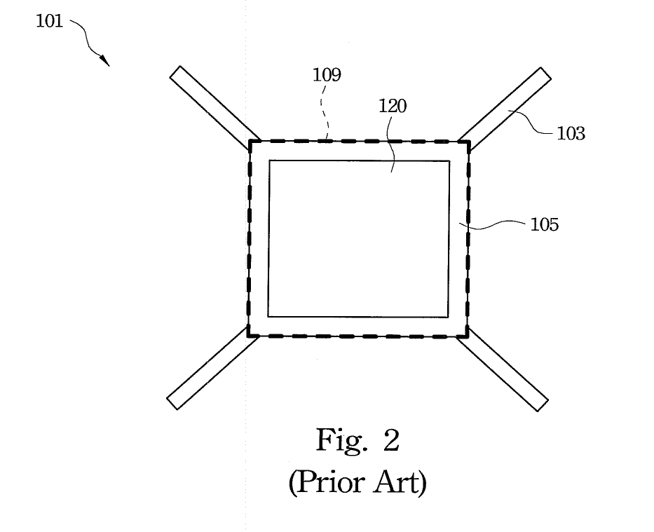

FIG. 3 is a cross-sectional diagram of a chip package structure during molding process in prior art;

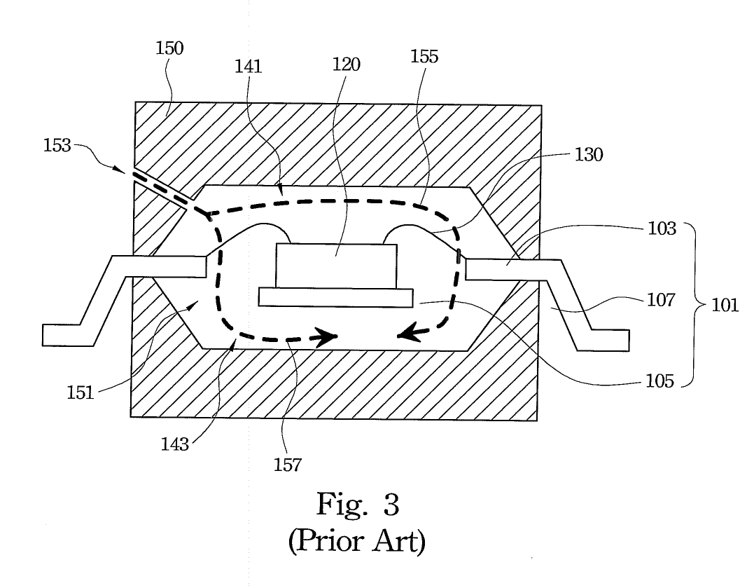

FIG. 4 is a cross-sectional diagram of a chip package structure after completion of molding process in prior art;

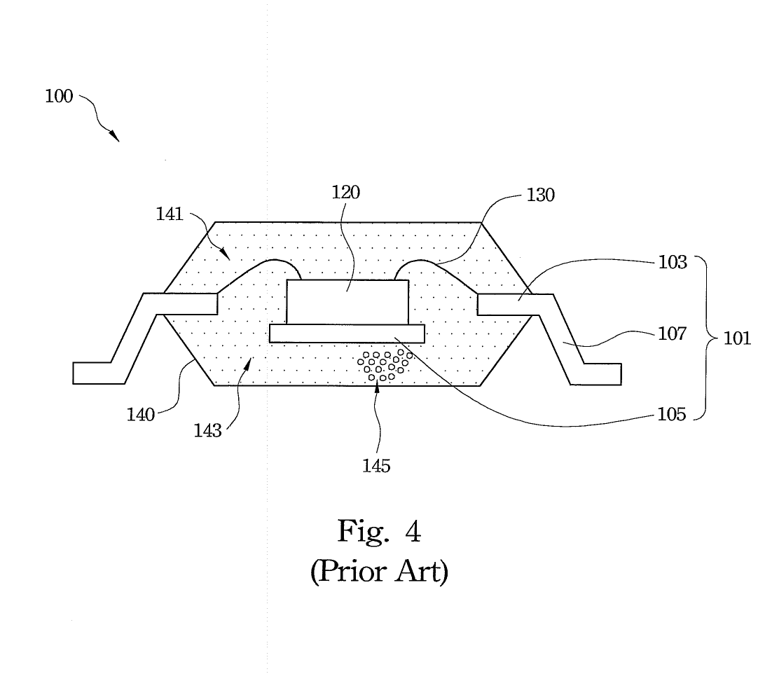

FIG. 5 is a cross-sectional diagram of a chip package structure according to a preferred embodiment of the present invention;

FIG. 6 is a top view of a chip and a leadframe according to a preferred embodiment of the present invention;

FIG. 7A is a top view of a die pad according to another preferred embodiment of the present invention;

FIG. 7B is a top view of a die pad according to a further preferred embodiment of the present invention;

FIG. 7C is a top view of a die pad according to a still another preferred embodiment of the present invention; and

FIG. 7D is a top view of a die pad according to a still further preferred embodiment of the present invention.

### DETAILED DESCRIPTION OF THE PREFERRED EMBODIMENT

Accordingly, the present invention a chip package structure, wherein a die pad of which at least a notch is formed on at least one side and opposite to a mold gate, so as to overcome or at least improve the problem of defects such as air bubbles in the encapsulation. The details of the present invention are described as follows by preferred embodiments.

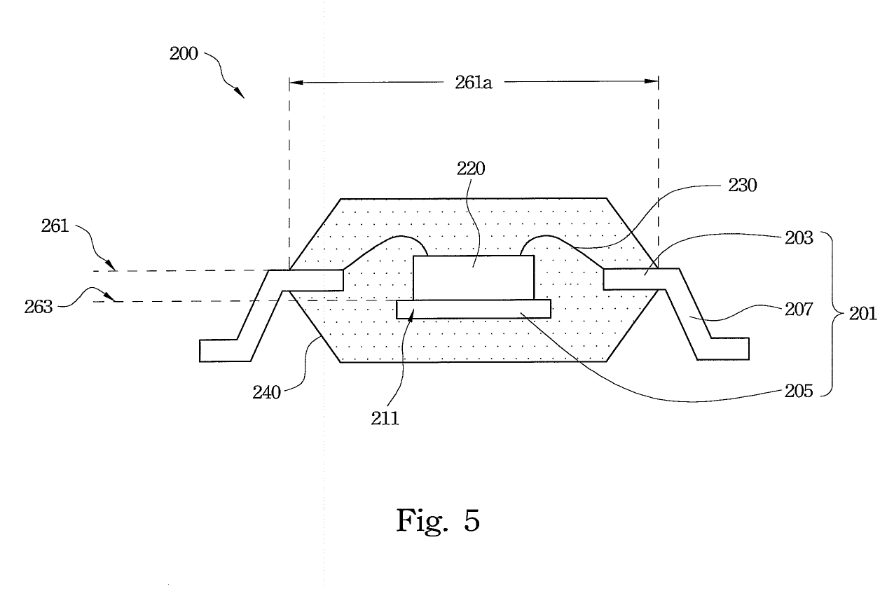

Reference is made to FIG. 5, which depicts a cross-sectional diagram of a chip package structure according to a preferred embodiment of the present invention. The chip package structure 200 may be a QFP structure which comprises a leadframe 201 having a plurality of internal leads 203 and a die pad 205, a chip 220 disposed on the die pad 205, a plurality of wires 230 electrically connecting the chip 220 with the internal leads 203, and an encapsulation 240 covering the leadframe 201, the chip 220 and the wires 230. At least a notch 211 is formed on at least one side of the die pad 205. Before the encapsulating material solidifies during the molding step, the notch 211 facilitates to overcome or at least improve the problem of defects such as air bubbles in the encapsulation 240.

In general, a material of the leadframe 201 may be copper, for example. The internal leads 203 forms a first planar surface shown as a dotted line 261, for defining a projection region 261a. The die pad 205 is disposed in the encapsulation 240 and has a second planar surface lower than the first planar surface formed by the internal leads 203, being so-called a “downset” die pad. External leads 207 typically are connected with the internal leads 203 and exposed from the encapsulation 240, so as to provide an electrical connection of the chip 220 with outside devices through the external leads 207.

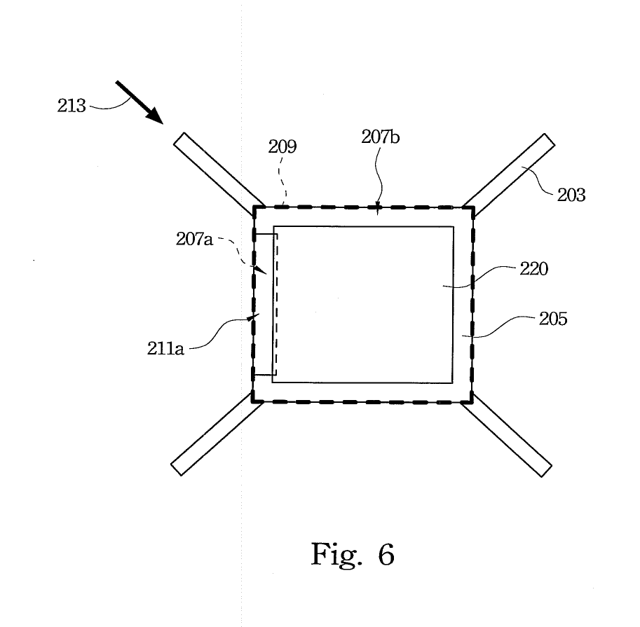

Reference is made to FIG. 6, which depicts a top view of a chip and a leadframe according to a preferred embodiment of the present invention. In this embodiment, a notch 211a is disposed on at least one side of the die pad 205, for example, a side 207a, and the notch 211a is disposed in a peripheral area 209 of the die pad 205 and opposite to a mold gate (not shown), wherein the encapsulation material is injected from the mold gate in a direction as indicated by an arrow 213. Alternatively, the notch 211a is also disposed on another side 207b of the die pad 205 and opposite to a mold gate. In other words, the notch 211a is optionally disposed on the side 207a and/or side 207b of the die pad 205. During the subsequent molding step, this design can accelerate the injection of the encapsulating material.

The area of the chip 220 is smaller than the peripheral area 209 of the die pad 205, and the chip 220 covers a portion of the notch 211a. In an example of FIG. 6, since the area of the chip 220 is smaller than the peripheral area 209 of the die pad 205, and the chip 220 covers a portion of the notch 211a, a contact area between the die pad 205 and the chip 220 may range from 10 percent to 80 percent of the area of the chip 220.

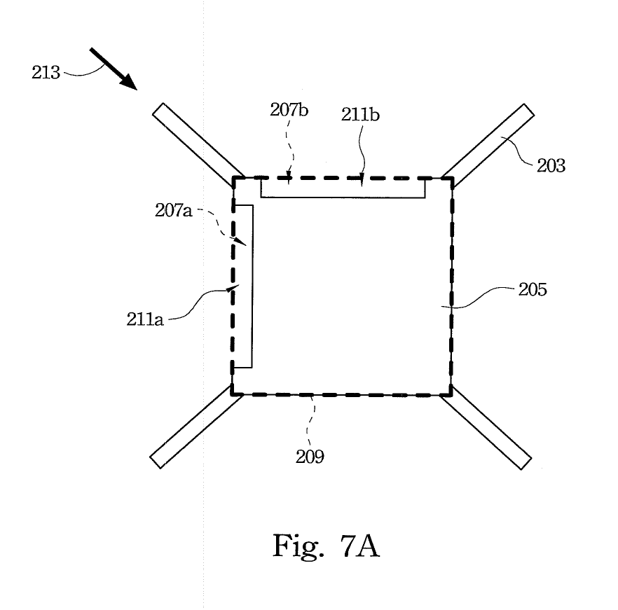

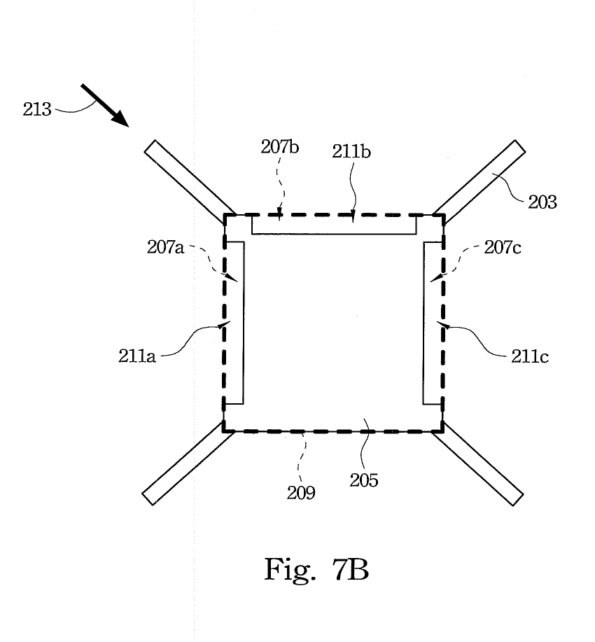

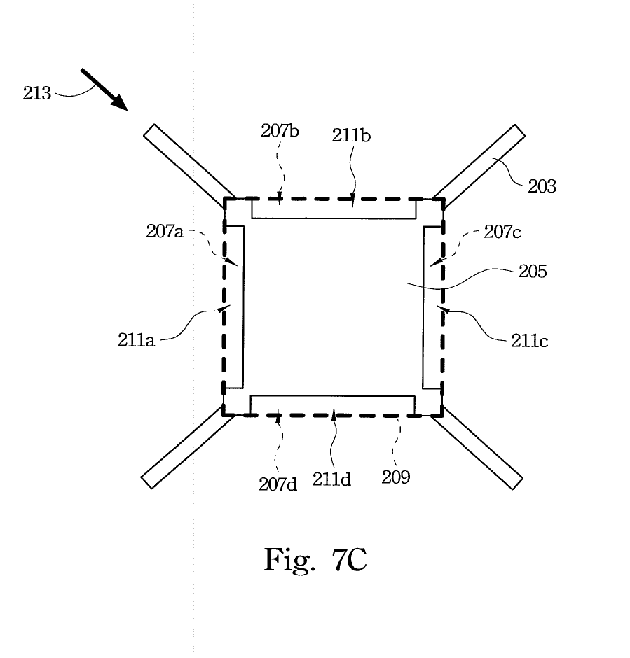

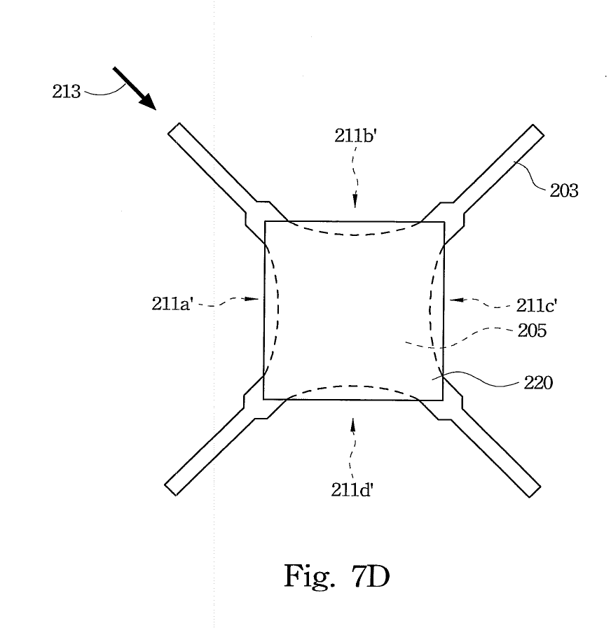

In addition to the notch disposed on the side of the die pad and opposite to the mold gate, there are also other notches disposed on other sides of the carrier according to other embodiments of the present invention facilitate accelerating the injection of the encapsulating material. Reference is made to FIG. 7A, which depicts a top view of a die pad according to another preferred embodiment of the present invention. In this embodiment, notches 211a and 211b are respectively disposed on at least two sides 207a and 207b of the die pad 205, for example. The notches 211a and 211b are also in the peripheral area 209 of the die pad 205, and one of the notches 211a and 211b opposite to the molding gate (not shown), wherein the encapsulation material is injected from the mold gate in a direction as indicated by the arrow 213. Besides, reference is made to FIG. 7B, which depicts a top view of a die pad according to a further preferred embodiment of the present invention. In this embodiment, notches 211a, 211b and 211c are respectively disposed on at least three sides 207a, 207b and 207c of the die pad 205, for example. The notches 211a, 211b and 211c are also in the peripheral area 209, and one of the notches 211a, 211b and 211c opposite to the molding gate (not shown), wherein the encapsulation material is injected from the mold gate in a direction as indicated by the arrow 213. Alternatively, reference is made to FIG. 7C, which depicts a top view of a die pad according to still another preferred embodiment of the present invention. In this embodiment, notches 211a, 211b, 211c and 211d are respectively disposed on four sides 207a, 207b, 207c and 207d of the die pad 205, for example. The notches 211a, 211b, 211c and 211d are also in the peripheral area 209, and one of the notches 211a, 211b, 211c and 211d opposite to the molding gate (not shown), wherein the encapsulation material is injected from the mold gate in a direction as indicated by the arrow 213. Despite various numbers of notches applied in several preferred embodiments, however, as long as any notch is disposed on the side of die pad and opposite to the molding gate, other notches, either on other sides and/or in various numbers, also can facilitate to accelerating the injection of the encapsulating material in the subsequently molding step.

Reference is made to FIG. 7D, which depicts a top view of a die pad according to a still further preferred embodiment of the present invention. In comparison with the rectangular notches (such as the notch 211 on FIG. 6; the notches 211a and 211b on FIG. 7A; the notches 211a, 211b and 211c on FIG. 7B; the notches 211a, 211b, 211c and 211d on FIG. 7C) in the above embodiments, notches 211a′, 211b′, 211c′ and 211d′ in this embodiment are curved. However, shapes and/or numbers of the aforementioned notches are exemplarily illustrated of the present invention rather than limiting the scope of the present invention. As is understood by a person skilled in the art, the notches, for example, in a rectangular, curved or any other notch shapes, can also be applied in the present invention, rather than being limited to the aforementioned shapes and/or numbers.

Therefore, according to the aforementioned preferred embodiments, one advantage of the chip package structure of the present invention has at least one notch formed on at least one side of the die pad to contribute to accelerating the injection of an encapsulating material, so as to exhaust the air in the mold in time, before the encapsulating material solidifies during the molding step, thereby overcoming or at least improve the problem of defects such as air bubbles in the encapsulation.

As is understood by a person skilled in the art, the foregoing preferred embodiments of the present invention are illustrated of the present invention rather than limiting of the present invention. It is intended to cover various modifications and similar arrangements included within the spirit and scope of the appended claims. Therefore, the scope of which should be accorded the broadest interpretation so as to encompass all such modifications and similar structure.

What is claimed is:

1. A chip package structure, comprising:
a leadframe, wherein the leadframe comprises:
a plurality of internal leads forming a first planar surface for defining a projection region; and
a die pad disposing in an encapsulation and having a second planar surface lower than the first planar surface, wherein at least one side of the die pad has a notch disposed thereon, the notch is disposed in a peripheral area of the die pad and opposite to a mold gate;
a chip disposed on the die pad, wherein an area of the chip is smaller than the peripheral area and the chip covers a portion of the notch;
a plurality of wires electrically connecting the chip with the internal leads; and
an encapsulation covering the chip, the die pad, the internal leads and the wires.

2. The chip package structure according to claim 1, wherein the notch is a rectangular notch.

3. The chip package structure according to claim 1, wherein the notch is a curved notch.

4. The chip package structure according to claim 1, wherein a contact area between the die pad and the chip ranges from 10 percent to 80 percent of the area of the chip.

5. The chip package structure according to claim 1, wherein the leadframe further comprises a plurality of external leads connecting the internal leads respectively, and the external leads are exposed from the encapsulation.

6. The chip package structure according to claim 1, wherein a material of the leadframe is made of copper.

7. The chip package structure according to claim 1, wherein at least two sides of the die pad have a notch, respectively, and one of the notches opposite to the mold gate.
